(19) United States
(12) Patent Application Publication
(10) Pub. No.: US 2005/0171741 A1
(43) Pub. Date: Aug. 4, 2005

(54) Communication apparatus and communication method

(75) Inventor: Miwako Doi, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/022,778

(22) Filed: Dec. 28, 2004

(30) Foreign Application Priority Data
Jan. 14, 2004 (JP) 2004-006791

(51) Int. Cl. G05B 13/02; H03F 1/26; G06F 15/00; H04B 15/00; G06K 9/68; G06K 9/70; G06K 9/00

(52) U.S. Cl. 702/189; 700/47; 382/115

(57) ABSTRACT

A communication apparatus includes a sensor input portion, a distributed sensor storage portion which stores sensor information from the sensor input portion in association with sensor type information or an attribute, a distributed ambient behavior processing portion which performs processing of recognition based on the sensor information stored in the distributed sensor storage portion, a certainty factor grant portion which grants a certainty factor in accordance with a result of recognition of the distributed ambient behavior processing portion, and a distributed ambient behavior storage portion which stores the result of recognition of the distributed ambient behavior processing portion as recognition information and the certainty factor granted by the certainty factor grant portion in association with the sensor information of the distributed sensor storage portion.

### CROSS-REFERENCE TO RELATED APPLICATIONS

This application is based upon and claims the benefit of priority from the prior Japanese Patent Application No. 2004-6791, filed on Jan. 14, 2004, the entire contents of which are incorporated herein by reference.

### BACKGROUND OF THE INVENTION

1. Field of the Invention

The present invention relates to a communication apparatus responding to a situation naturally for a user in accordance with an ever-changing certainty factor about positional recognition or personal recognition attained from sensing information acquired from various distributed sensors and so on.

2. Description of the Related Art

GUI (Graphical User Interface) for performing operations by pointing an iron or a menu on a screen using a keyboard or a mouse has made a great contribution to improvement in production efficiency in offices. On the other hand, in home or the like, there is a request to have a dialog natural for human beings using gestures or natural languages without using any keyboard or any mouse.

To meet this request, there have been developed systems for making questions and answers in natural languages, dialog systems for having a dialog with robots by gestures, and so on. In the field of artificial intelligence, several methods in which likelihood of a topic of a dialog or likelihood of situational recognition of a human being to be a partner of the dialog is used as a certainty factor (strictly the contents of those parameters are not synonymous) so as to make the dialog acceptable for the human being have been proposed for the dialog systems.

For example, according to some systems, when there is a question from a user, a knowledge base is retrieved, and an answer is created using a certainty factor (likelihood, or degree of pattern matching) of the result of retrieval of the knowledge base. In these question answering systems, an answer having the highest certainty factor to a question is found, and an answer sentence is created. Here it is disclosed that when answers having one and the same certainty factor are found, a question as to which answer is desired is thrown back to the human being (for example, see Sadao Kurohashi, “Automatic Question Answering Based On Large Text Knowledge Base”, Invited talk at 3rd Symposium on Voice Language, Technical Report of the Institute of Electronics, Information and Communication Engineers, December, 2001).

There have been also proposed systems in which the degree of intrusiveness on the system side is divided and defined as the degree of dominance, the degree of boldness and the degree of information provision in accordance with a certainty factor so as to control creation of an answer sentence (for example, Toru Sugimoto et al., “Dialogue Management for a Secretary Agent and Its Adaptive Features”, The 16th Annual Conference of Japanese Society for Artificial Intelligence, 2B3-02, 2002). The control is carried out as follows. That is, when the certainty factor is so high that the sum of the certainty factor and the degree of dominance or the degree of boldness is higher than 1, decision-making is not committed to the human being but to the system side. On the contrary, when the certainty factor is so low that the sum of the certainty factor and the degree of dominance not higher than 1, the system side only provides information.

In these background-art techniques, probabilities belonging to individual knowledge units each having a knowledge base for determining a certainty factor are deterministic. There may appear a change in the method for calculating the certainty factor when a new knowledge unit is added, or when the domain (field) of a knowledge unit to be used is changed in accordance with the characteristic of a human being to be a partner of communication. Once the method is changed, one and the same certainty factor is calculated for one and the same question.

In a natural dialog between human beings, even in response to one and quite the same question, different knowledge may be retrieved and answered in accordance with specialized knowledge belonging to a receiver, a field (domain) interested in by the receiver, or something of current interest of the receiver. In such a manner, the certainty factor of a result of retrieval of knowledge should change in accordance with the situation of the receiver. On the other hand, any existing system has a problem that one and the same certainty factor is provided for one and the same question sentence so that a natural dialog cannot be obtained.

Further, even if a human being to be a speaker of a dialog makes one and the same question, a question sentence received by a receiver may differ from case to case due to influence of speaker's utterance, noise or the like. When the receiver is a system, a question sentence provided as a text to the system may differ from case to case due to influence of speaker's utterance or noise or due to a change of a result of voice recognition.

On the other hand, when voice recognition is used for input, certainty factors indicating the likelihood of recognized words may be used. However, these certainty factors are used as the likelihood of a syntax when the recognized words are combined. That is, the accuracy of the voice recognition serves to obtain a result of recognition, and is used only as likelihood of a question sentence as a result of recognition. A subsequent dialog system is not controlled in accordance with the certainty factor of each recognized word. Therefore, there is another problem that a natural dialog cannot be obtained.

There is a robot designed to evaluate external stimulus information such as sensor information, determine whether it means an approach from a user or not, digitize an external stimulus into predetermined parameters for each user's approach, decide an action based on the parameters, and operate each portion of the robot based on the decided action (for example, see JP2002-178282 (kokai)). However, when, for example, the user is at a distant place and has no approach to the robot, the influence of the user as an external stimulus to be acquired by the robot is not parameterized, that is, not used as a certainty factor for dialog control.

### SUMMARY OF THE INVENTION

As described above, a deterministic probability granted to a knowledge base is used as a certainty factor serving to control a dialog such as an answer to a question sentence. Accordingly, for one and the same input sentence, a fixed certainty factor is obtained independently of context or ambient condition. Thus, there is a problem that only an unvaried answer can be expected. In addition, in dialog control of a robot using an external stimulus, the external stimulus is imported and used as parameters only when a user approaches the robot. Accordingly, there is another problem that dialog control cannot be made continuously using ambient information as a certainty factor. Further, even when dialog control of a robot is performed using a certainty factor, the certainty factor is calculated deterministically, and not varied in accordance with ambient information.

That is, since there is no mechanism for varying the certainty factor not only in accordance with the contents or the partner of a dialog but also in accordance with the ambient information, there is a problem that continuous dialog control cannot be attained.

According to an aspect of the present invention, a communication apparatus includes a sensor input portion, a distributed sensor storage portion which stores sensor information from the sensor input portion in association with sensor type information or an attribute, a distributed ambient behavior processing portion which performs processing of recognition based on the sensor information stored in the distributed sensor storage portion, a certainty factor grant portion which grants a certainty factor in accordance with a result of recognition of the distributed ambient behavior processing portion, and a distributed ambient behavior storage portion which stores the result of recognition of the distributed ambient behavior processing portion as recognition information and the certainty factor granted by the certainty factor grant portion in association with the sensor information of the distributed sensor storage portion.

According to another aspect of the present invention, a communication method includes storing sensor information from a sensor input portion in association with sensor type information or an attribute by means of a distributed sensor storage portion, performing processing of recognition based on the sensor information by means of a distributed ambient behavior processing portion, granting a certainty factor in accordance with a result of recognition of the distributed ambient behavior processing portion by means of a certainty factor grant portion, and storing the result of recognition and the certainty factor in association with the sensor information of the distributed sensor storage portion by means of a distributed ambient behavior storage portion.

According to the configuration of the invention, a robot or the like has a dialog based on a certainty factor updated at any time, so that a non-weighted natural dialog can be obtained with acquired necessary information, and continuous dialog control can be performed.

### BRIEF DESCRIPTION OF THE DRAWINGS

FIG. 1 is a block diagram showing the schematic configuration of a communication apparatus according to an embodiment of the invention;

FIG. 2 is a schematic view showing the implementation of the embodiment of the invention;

FIG. 3 is a diagram showing an example of description of a distributed sensor information DB about a camera;

FIG. 4 is a diagram showing an example of description of a distributed sensor information DB about a microphone;

FIG. 5 is a diagram showing an example of description of a distributed sensor information DB about a position sensor;

FIG. 6 is a block diagram showing the detailed configuration of a distributed ambient behavior processing portion;

FIG. 7 is a diagram showing an example of description of a distributed state information DB;

FIGS. 8A to 8D are views for explaining face detection from a camera;

FIGS. 9A and 9B are diagrams for explaining a normalized pattern and a feature vector of a face image;

FIG. 10 is an explanatory view of detection of a body direction;

FIG. 11 is a diagram showing an example of description of a distributed behavior information DB;

FIG. 12 is a diagram showing an example of behavior conclusion rules;

FIG. 13 is a diagram showing an example of a dialog template; and

FIG. 14 is a diagram showing an example of description of a human beings-things interaction DB.

### DETAILED DESCRIPTION OF THE INVENTION

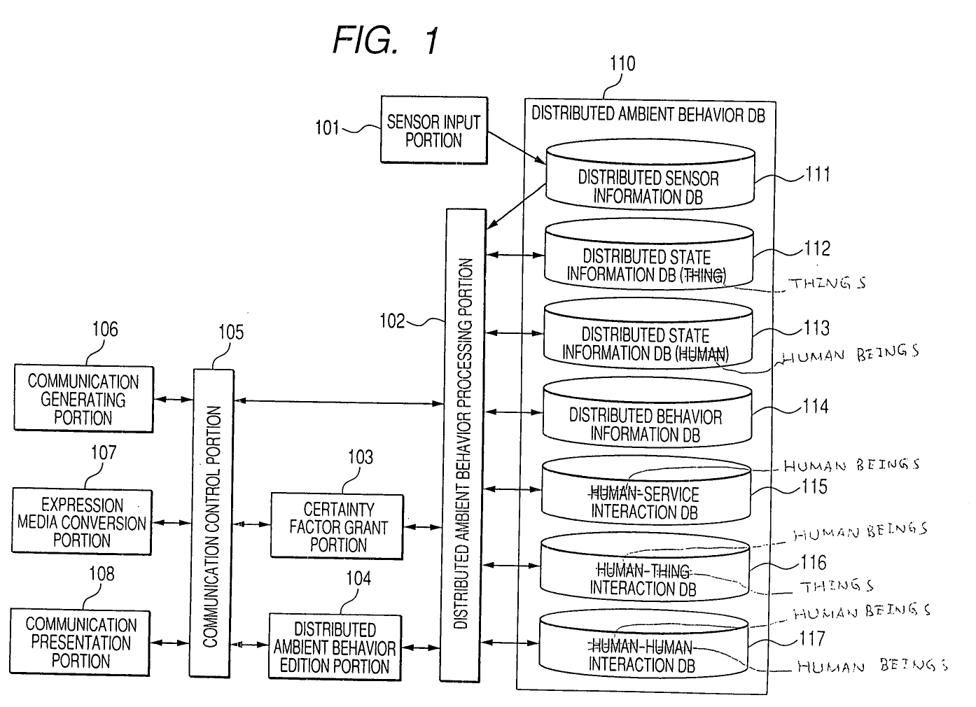

An embodiment of the invention will be described with reference to the drawings. FIG. 1 is a block diagram showing the schematic configuration of a communication apparatus according to the embodiment.

The communication apparatus is constituted by a sensor input portion 101, a distributed ambient behavior DB (DataBase) 110, a distributed ambient behavior processing portion 102, a certainty factor grant portion 103, a distributed ambient behavior edition portion 104, a communication control portion 105, a communication generating portion 106, an expression media conversion portion 107, and a communication presentation portion 108. The sensor input portion 101 is comprised of a plurality of distributed sensors such as RF (Radio Frequency) tags, photo-sensors, microphones, cameras, etc. The distributed ambient behavior DB 110 stores sensor information input from the sensor input portion 101 and results of recognition thereof. The distributed ambient behavior processing portion 102 performs various processes such as voice recognition, image recognition and position identification based on radio intensity, on the information from the sensor input portion 101. The certainty factor grant portion 103 grants certainty factors based on the sensor information from the sensor input portion 101 or the information stored in the distributed ambient behavior DB 110. The distributed ambient behavior edition portion 104 edits the information and the certainty factors stored in the distributed ambient behavior DB 110 at any time or in real time based on the information from the sensor input portion 101. The communication control portion 105 performs communication control based on the information and the certainty factors stored in the distributed ambient behavior DB 110. The communication generating portion 106 generates a communication to be presented to a user based on the control of the communication control portion 105. The expression media conversion portion 107 converts the generated result of the communication generating portion 106 into media a robot can present. The communication presentation portion 108 presents the converted result of the expression media conversion portion 107.

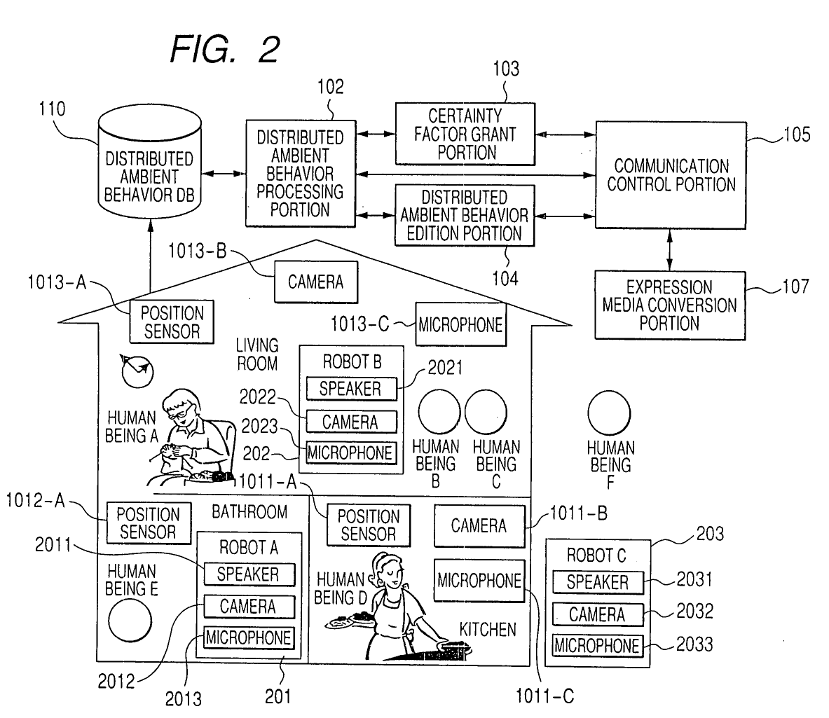

FIG. 2 shows the state where a plurality of sensor input portions 101 are installed in home. Various sensors are installed in home, including smoke sensors, temperature sensors, strain sensors, pressure sensors, etc. Here are shown only position sensors using RF tags, photo-sensors or the like, cameras and microphones, which will be used for description.

For example, a robot A (201) serving as a watcher is in the bathroom on 1F, a robot B (202) serving as a partner of communication is in the living room on 2F, and a robot C (203) serving as a watchdog is outside. Various sensors such as ultrasonic sensors or infrared sensors for detecting barriers when needed by the robots intending to move are attached to the robots A to C (201 to 203). However, here are shown only the sensors such as cameras, microphones, etc. which will be used for description.

Cameras (movie cameras) 2012, 2022 and 2032 for determining a situation, for example, determining whether a human face is included or not, performing personal authentication based on the distinguished face, detecting the face direction, or determining whether there is a moving body or not, are attached to the robots respectively. The cameras 2012, 2022 and 2032 do not have to share the same specifications. For example, since the robot C 201 is provided for watching, an infrared camera workable in the nighttime or a high speed camera capable of photographing at 60 or more pieces per second (about 30 pieces per second in the case of normal cameras) enough to distinguish a moving body moving at a high speed, can be used as the camera 2032. On the other hand, the robot A (201) or the robot B (202) is intended to talk with human beings. When a stereo type camera (twin-lens camera) is used, not only is it possible to recognize a distance, but it is possible to put a confronting person at rest because the robot can talk with two eyes to the person. Alternatively, in the case of the robot A 201 serving as a dry nurse, a water-proof camera or the like may be used because the robot deals with a child. One robot may have a plurality of cameras, for example, one of which is a normal camera to be used in the daytime with high intensity of illumination, and the other of which is an infrared camera to be used in the nighttime with low intensity of illumination. Further, as for the resolution of cameras, a high resolution camera or a low resolution camera may be used selectively in each robot. In order to save power, a surveillance camera or the like may be used in combination with an infrared sensor or the like, so that the camera picks up an image only when a motion is detected. Such selective use is also applicable to a camera 1011-B or a camera 1013-B installed in a room of the home.

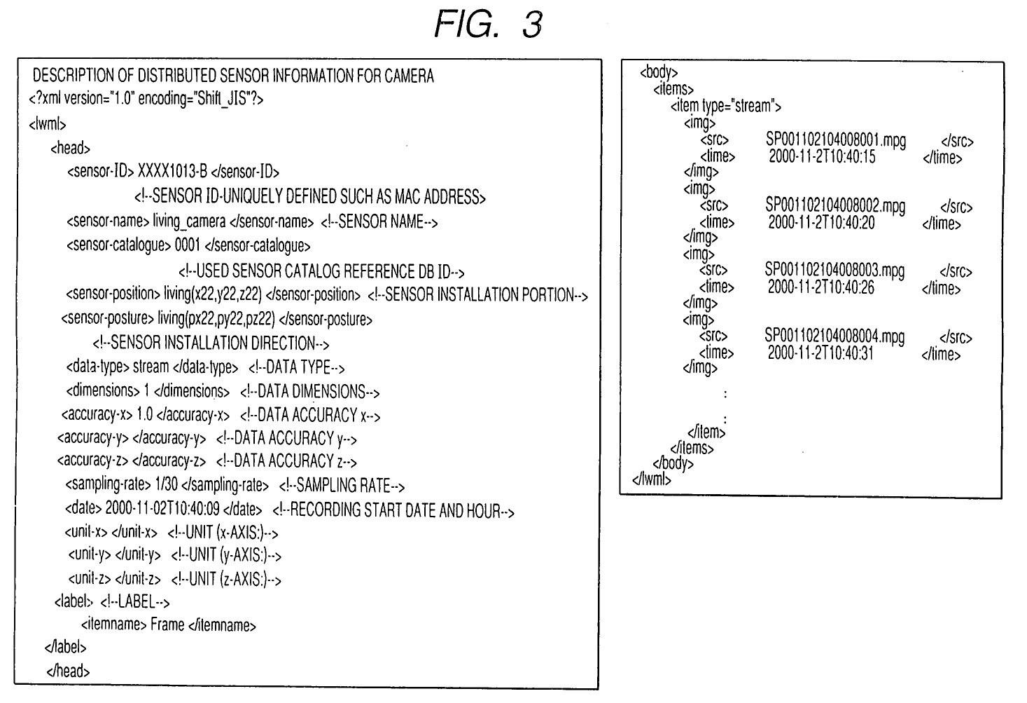

For example, a result photographed by the camera 1013-A installed in the living room is accumulated in a distributed sensor information DB 111 of the distributed ambient behavior DB 110 as sensor information from the sensor input portion 101 together with the accuracy of the sensor. Information accumulated in the distributed sensor information DB 111 has a format as shown in FIG. 3.

Each data entry of all the cameras, the microphones and the other sensors is described with a head including a sensor ID such as a machine (MAC) address defined uniquely, a sensor name, an ID in a catalog reference DB which ID is needed for reference to the sensor performance, function, etc., a site where the sensor is installed, a type of data acquired by the sensor, dimensions of the data, accuracy of the data, a sampling rate in acquisition of the sensor data, recording start date and hour, units of the acquired data, and a label of the acquired data. The accuracy of the data and the units of the data are described dependently on the dimensions of the data.

The head is followed by a data body described in a portion between the tags <body> and </body>. In this case, for example, data photographed by a camera are image data at 30 frames per second. Each image picked up by a normal video camera is comprised of two-dimensional data of 640 pixels by 480 pixels. However, since one frame forms a unit, the data are regarded as one-dimensional, and the sampling rate is 1/30. For example, individual data are formed as files compressed by MPEG2 (Motion Picture Expert Group, phase 2) as described in the portion between the tags <body> and </body>. Each file is described as its file name and its time stamp at the file end.

Here, the data are accumulated as MPEG2 files by way of example. The data format is not always limited to MPEG2. There are various movie supporting formats such as MotionJPEG, JPEG2000, avi, MPEG1, MPEG4, DV, etc. Any format may be used.

Since the accuracy is one-dimensional, only the tag <accuracy-x> is described. Here, the accuracy is 1.0. That is, it indicates that photographing is performed in the same condition as that when the camera was installed. The accuracy will be a value smaller than 0.1 when the camera cannot pick up an image in performance meeting the catalog values, for example, when a flash cannot be used in spite of a shortage of intensity of illumination, or when an image is taken against the direct sunlight pouring directly into the camera, or when the camera is short of electrical charge.

In addition, the robots A to C (201 to 203) are provided with microphones 2013, 2023 and 2033 respectively. Each microphone is provided for personal authentication based on human voice or recognition of a situation as to whether there is a moving body or not. In the same manner as the cameras, the microphones do not have to share the same specifications.

For example, a microphone array using two microphones to enhance the directivity may be used for gathering sounds within a certain range. Alternatively, a sound-gathering microphone combined with an infrared sensor or the like for gathering sounds only when a motion is detected may be used in order to save power. Such selective use is also applicable to a microphone 1011-C or a microphone 1013-C installed in a room of the home.

For example, a result of sound gathered by the microphone 1013-C installed in the living room is accumulated in the distributed sensor information DB 111 of the distributed ambient behavior DB 110 as sensor information from the sensor input portion 101 together with the accuracy of the sensor. Information accumulated in the distributed sensor information DB 111 has a format as shown in FIG. 4.

The information format in FIG. 4 is similar to the information format in FIG. 3. There is a difference between the information format in FIG. 4 and the information format in FIG. 3 in that the information in FIG. 4 has a wav format which is a sound data format while the aforementioned information of the cameras is described as MPEG files or the like in FIG. 3. The wav format is only an example. The data format is not always limited to the wav format. Any format including an MPEG format (MP3) may be used in the same manner as the movie format.

Since the accuracy is one-dimensional, only the tag <accuracy-x> is described. Here, the accuracy is 1.0. That is, it indicates that sound gathering is performed in the same condition as that when the microphone was installed. The accuracy will be a value smaller than 0.1 when the microphone cannot gather sounds in performance meeting the catalog values, for example, when the microphone is short of electrical charge.

As for sensors, in FIG. 2, position sensors 1011-A, 1012-A and 1013-A are installed in addition to the cameras and the microphones. There are various types of position sensors. Here, for example, assume that the following system is used. That is, the robots A to C (201 to 203) or human beings A to D have radio tags such as RFIDs, and the position sensors 1011-A, 1012-A and 1013-A detect weak radio waves from the radio tags. Radio tags are classified into an active type and a passive type. An active type radio tag transmits radio waves by itself. A passive type radio tag does not transmit radio waves by itself, but generates radio waves due to electromagnetic induction when the radio tag approaches a gate of a position sensor. Here, the robots A to C (201 to 203) or the human beings A to D put on active type radio tags respectively. For the case of human beings, radio tags may be attached to house slippers by way of example. Thus, the human beings are not aware of the radio tags so as not to feel the radio tags as burdens. However, in some case, a human being may not put on the house slippers. In consideration of such a case, the certainty factor of the position of the human being takes a value lower than 1.0.

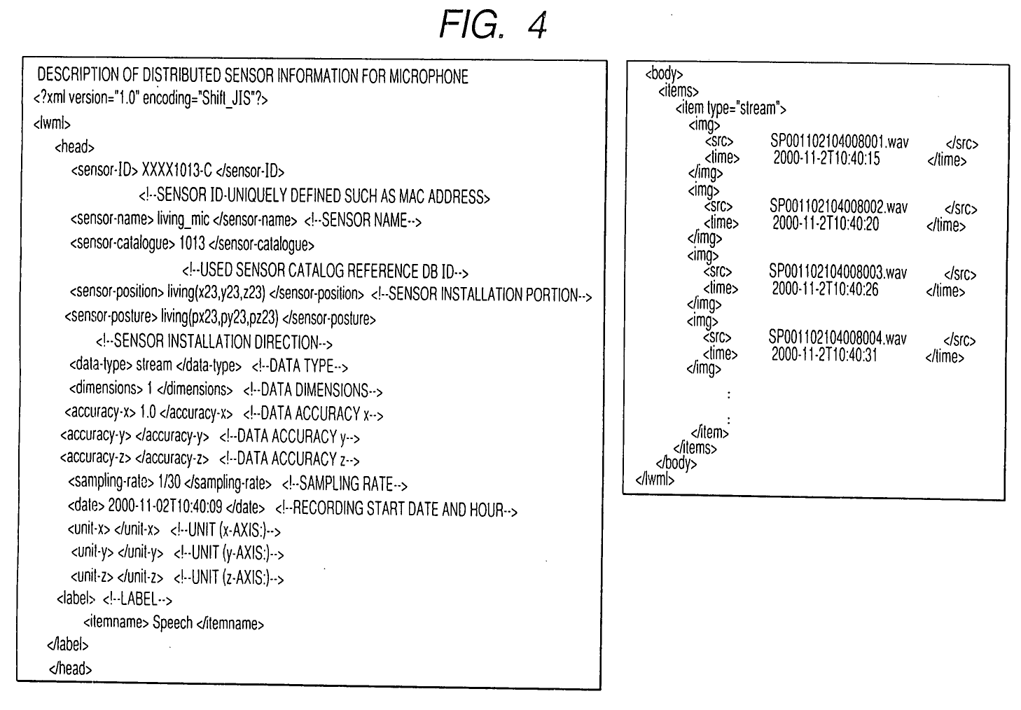

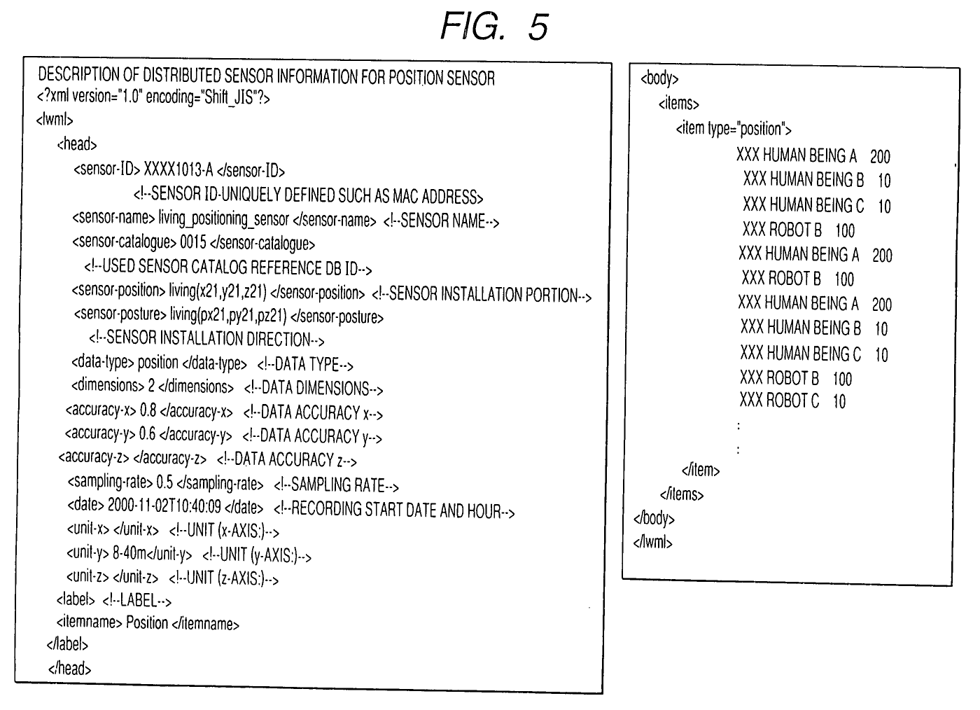

A result detected by the position sensor 1013-A in the living room is accumulated in the distributed sensor information DB 111 of the distributed ambient behavior DB 110 as sensor information from the sensor input portion 101 together with the accuracy of the sensor. Information accumulated in the distributed sensor information DB 111 has a format as shown in FIG. 5.

The information format in FIG. 5 is substantially similar to the information format in FIG. 3 or 4. There is a difference of the information format in FIG. 5 from the information format in FIG. 3 or 4 in that the data are two-dimensional, and the data are described directly in the portion between the tags <body> and </body> because the data does not have a volume as large as sound data or picture data.

Individual data include two kinds of data, that is, the number of a radio tag from which a radio wave was detected, and the intensity of the radio wave at that time. Here, in a way easy to understand, the radio tag number of a radio tag attached to the human being A is described as “XXX human being A”, and the radio tag number of a radio tag attached to the robot B (202) is described as “XXX robot B”. On the other hand, the radio wave intensity takes a value obtained by normalizing the radio wave intensity acquired by a position sensor in 256 steps from 0 to 255. Then, the radio wave intensity expressed by 255 is the most intensive, indicating the radio tag is present in the closest site. The lower the value of the radio wave intensity is, the farther the radio tag is. Since the radio wave intensity is in inverse proportion to the square of the distance, the 256 steps are not linear. The larger the step value is, the narrower the step range is. On the contrary, the smaller the step value is, the wider the step range is.

Assume that the human beings A to C, the robot B (202) and a plurality of radio tags are present in the living room as shown in FIG. 2. In this case, the position sensor 1013-A does not detect all the radio tags simultaneously, but detects them sequentially. Accordingly, detected results are described in time series as shown in FIG. 5. In this event, the human being B or the human being C is far from the position sensor 1013-A. Therefore, the radio wave is so weak that the radio wave does not always reach the human being B or C. Thus, the position sensor 1013-A may not detect the human being B or C. As shown in FIG. 5, the number of times with which the human being A or the robot B (202) is detected is larger. In some cases, the robot C (203) existing outside as shown in FIG. 5 may be detected. Accordingly, the accuracy about a detected radio tag ID is 1.0 or less. Here, the accuracy of this sensor is 0.8.

For example, assume that a radio tag has a communication distance of 10 m in the catalog. In this case, the radio tag can be detected at a distance of 10 m or more. The distance of 10 m or more means the radio waves from the radio tag reaches 10 m or more. In some cases, the radio waves may be detected actually up to 40 m. Further, due to the direction in which an antenna is attached, or the like, in fact, there is an individual difference in the distance the radio waves can reach. Thus, the range of the y-axis (the second data of two-dimensional data) is 8 to 40 m by way of example. The minimum value of 8 m indicates that the minimum value was 8 m in the data actually measured with radio tags installed in the living room in spite of the minimum value of 10 m in the catalog.

Radio wave intensity I is expressed by:

$$I = \frac{k}{{r}^{2}} \qquad [ Expression 1 ]$$

where k designates a coefficient, and r designates a distance. The radio wave intensity I in this case is a value of 256 steps.

Further, the accuracy about the distance is set to be 0.6 in consideration of fluctuation of arrival of radio waves to a position sensor due to the temperature, the number of persons in the room, or the like.

Here, though not described especially, other sensor information is also accumulated in the distributed sensor information DB 111 in the same manner as in FIGS. 3 to 5. The distributed ambient behavior processing portion 102 reads information accumulated in the distributed sensor information DB 111 sequentially, and classifies the read information into information about human beings and information about things. Further, the distributed ambient behavior processing portion 102 performs an appropriate recognition process. The result of the recognition process together with a certainty factor calculated by the certainty factor grant portion 103 based on the accuracy of sensor information is written into the distributed state information DB 112 by the distributed ambient behavior edition portion 104 when the result is related to a position or a posture about a thing, or conditions of a thing (moving or the like). The result is written into the distributed state information DB 113 likewise when the result is related to a position or a posture about a human being, or fundamental action information such as walking or rest.

Further, the distributed ambient behavior processing portion 102 reads information from the distributed sensor information DB 111, the distributed state information DB 112 and the distributed state information DB 113, and performs an appropriate recognition process. Based on the read sensor accuracy or certainty factors, a behavior such as sleeping, eating, watching TV, bathing, cooking, etc. is written in the distributed behavior information DB 114 together with a certainty factor of the behavior calculated by the certainty factor grant portion 103, by the distributed ambient behavior edition portion 104.

Further, the distributed ambient behavior processing portion 102 reads information from the distributed sensor information DB 111, the distributed state information DB 112, the distributed state information DB 113 and the distributed behavior information DB 114, and performs an appropriate recognition process. Based on the read sensor accuracy or certainty factors, when, for example, a human being is watching TV, the fact that the human being is using TV service is written into a human beings-service interaction DB 115 together with a certainty factor of the fact calculated by the certainty factor grant portion 103, by the distributed ambient behavior edition portion 104. When, for example, a human being is putting back dishes, the interaction between the human being and the thing is written into a human beings-things interaction DB 116 likewise. When, for example, the family members talk to each other, the interaction between the human beings is written into a human beings-human beings interaction DB 117 likewise.

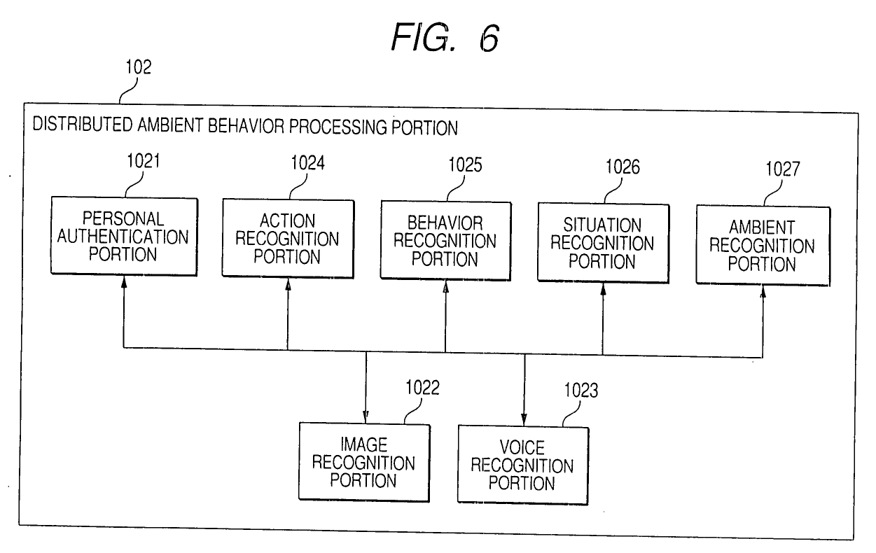

Description will be made about how to calculate a certainty factor and how to edit the distributed ambient behavior DB 110 based on the distributed sensor information shown in FIGS. 3, 4 and 5 by way of example. As shown in FIG. 6, the distributed ambient behavior processing portion 102 is constituted by a personal authentication portion 1021 for authenticating an existing human being as to whether the human being is one of family members or not, an action recognition portion 1024 for recognizing an action of the human being, a behavior recognition portion 1025 for recognizing a behavior, a situation recognition portion 1026 for recognizing a situation, an ambient recognition portion 1027 for recognizing an ambience including things or services, an image recognition portion 1022 for performing basic recognition processes for the aforementioned recognition processes, and a voice recognition portion 1023.

Here, with reference to FIG. 6, description will be made about how the position and action of the human being A were recognized by the action recognition portion 1024 and the personal authentication portion 1021 using the sensor information of the distributed sensor information DB 111, and described in the distributed state information DB 113. Recognition and description about the distributed state information DB 112 related to things are substantially similar to those about the distributed state information DB 113. Therefore, only the distributed state information DB 113 will be described here.

The action recognition portion 1024 retrieves the information about the position sensor 1013-A in the distributed sensor information DB 111 as shown in FIG. 5, and acquires the fact that the position of the human being A have been detected a plurality of times. The position sensor 1013-A is a sensor located in the living room as shown in FIG. 5. Therefore, the detected position is in the living room.

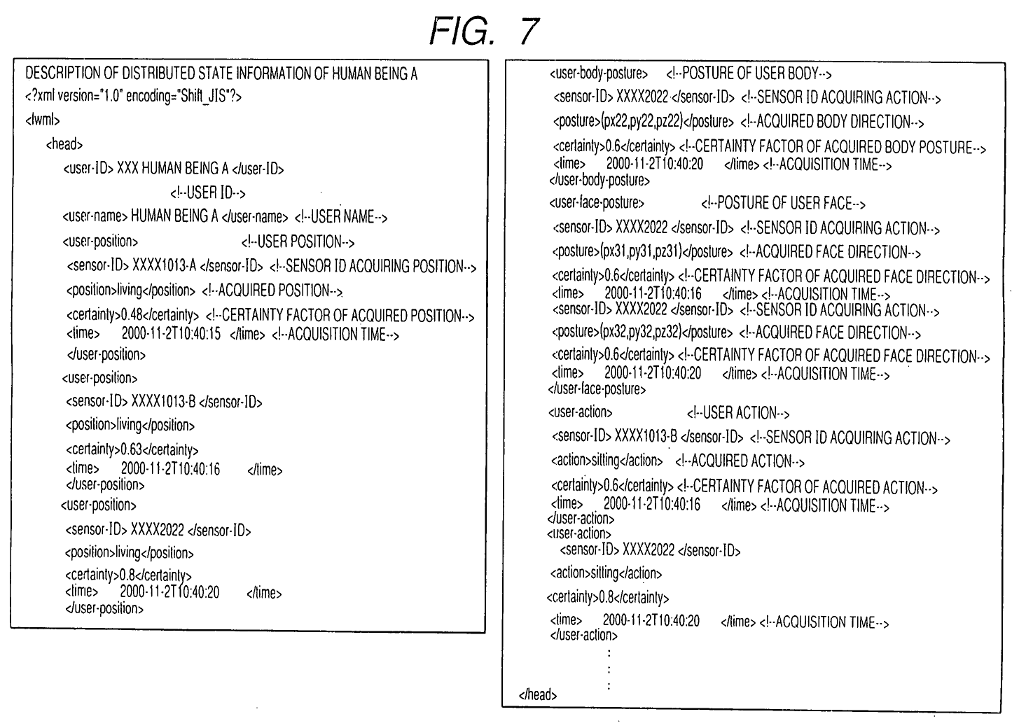

The certainty factor grant portion 103 calculates the certainty factor of the position of the human being acquired by the position sensor 1013-A as 0.8×0.6=0.48 based on the fact that the accuracy of acquisition of the position sensor 1013-A is 0.8 about the human being and 0.6 about the detected radio wave intensity from FIG. 5. For example, as shown in FIG. 7, the calculated certainty factor is additionally described in the distributed state information DB 112 by the distributed ambient behavior edition portion 104.

The camera 1013-B and the microphone 1013-C are installed in the living room. The camera 2022 and the microphone 2023 of the robot B (202) existing in the living room also records information about the human being A. Here, description will be made on an example in which photographing and personal recognition/authentication are performed concurrently in the camera 1013-B and the camera 2022. Similar processes are performed in the microphones 1013-C and 2023, and description thereof in FIG. 7 will be omitted here for the sake of simplification.

Whether the human being A is picked up by the camera 1013-B or the camera 2022 is examined by the personal recognition/authentication portion 1021 and the image recognition portion 1022 as follows.

First, data picked up by the camera 1013-B or the camera 2022 are accumulated as MPEG2 data here as shown in FIG. 3. A face image is detected to determine a detected moving body. A face region is extracted by detecting a region of a face or a region of a head from an image file.

There are some face region extraction methods. For example, according to one of the methods, color information is used when a picked-up image is a color image. Specifically, the color image is converted from a RGB color space to a HSV color space, and a face region or a hair portion is separated by region division using color information such as hue or chromo. Divided partial regions are extracted using a region merging method etc. According to another face region extraction method, a face detection template provided in advance is moved within an image so as to obtain a correlation value. A region having the highest correlation value is detected as a face region. According to another method, an eigenface method or a subspace method is used instead of the correlation value, so as to obtain a distance or a similarity measure and extract a portion having the smallest distance or the largest similarity measure. There is another method in which infrared light is projected independently of a normal CCD camera, and a region corresponding to a face to be extracted is cut out based on reflected light thereof. Here, anyone of the aforementioned methods and other methods may be used.

To determine whether the extracted face region includes a face or not, the positions of eyes are detected on the face region. The detection may be based on a method using pattern matching in the same manner as in the face detection, or a method for extracting face feature points such as pupils, nostrils, corners of a mouth, etc. from a movie (for example, see Kazuhiro Fukui and Osamu Yamaguchi, “Facial Feature Point Extraction Method Based on Combination of Shape Extraction and Pattern Matching”, Denshi-Jouhou Tsuushin Gakkai Ronbun-shi, Vol. J80-D-II, No. 8, pp. 2170-2177, 1997). Here, any one of the aforementioned methods and other methods may be used.

Here, based on the extracted face region and face parts detected from the face region, a region having defined dimensions and shape is cut out from the positions of the detected face parts and the position of the face region. Shading information of the cut-out region is extracted from the input image as a feature quantity for recognition. Of the detected face parts, two parts are selected. When a line segment connecting the two parts is within the extracted face region at a defined ratio, the region is converted into a region of m pixels by n pixels, and formed into a normalized pattern.

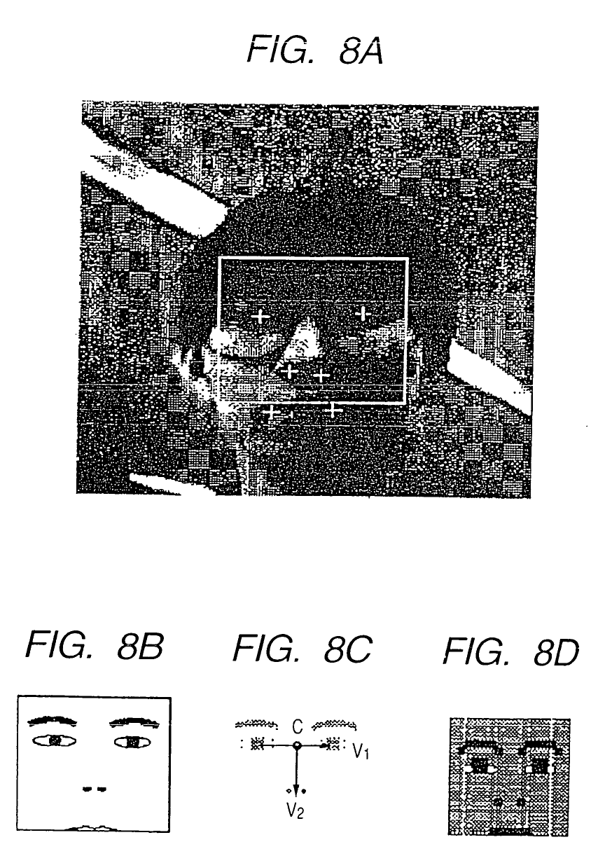

FIGS. 8A to 8D show an example in which both eyes are selected as the face parts. FIG. 8A shows a face image picked up by the imaging input means, on which image an extracted face region is illustrated by a white rectangle, and detected face parts are illustrated as white crosses superimposed thereon. FIG. 8B schematically shows the extracted face region and the face parts. When there is a defined ratio between distances to the parts from the middle point of the line segment connecting the right and left eyes as shown in FIG. 8C, the face region is converted into shading information, and formed into shading matrix information of m pixels by n pixels as shown in FIG. 8D. Hereinafter, a pattern as shown in FIG. 8D will be referred to as a normalized pattern. When a normalized pattern as shown in FIG. 8D is cut out, it is considered that at least a face is detected.

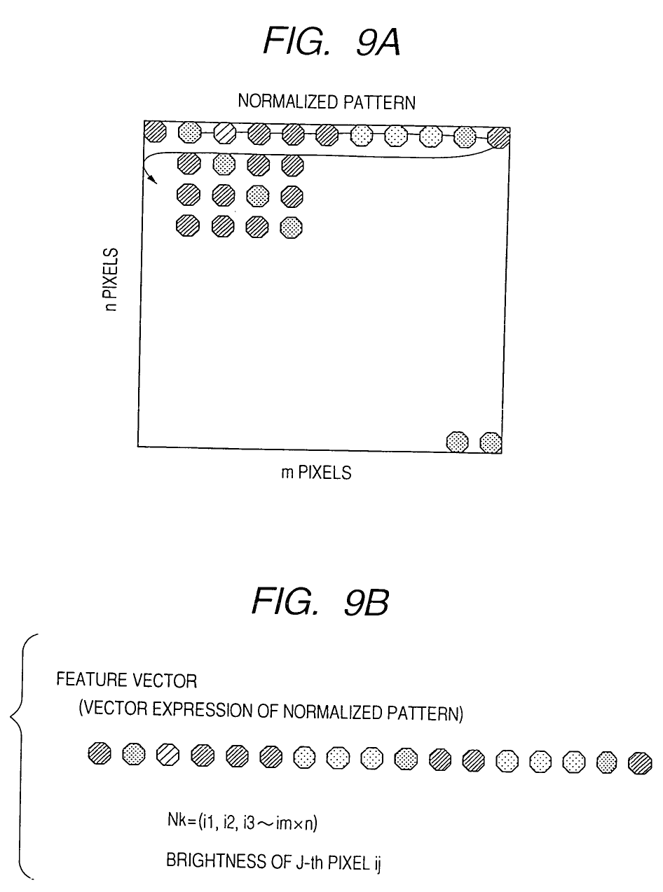

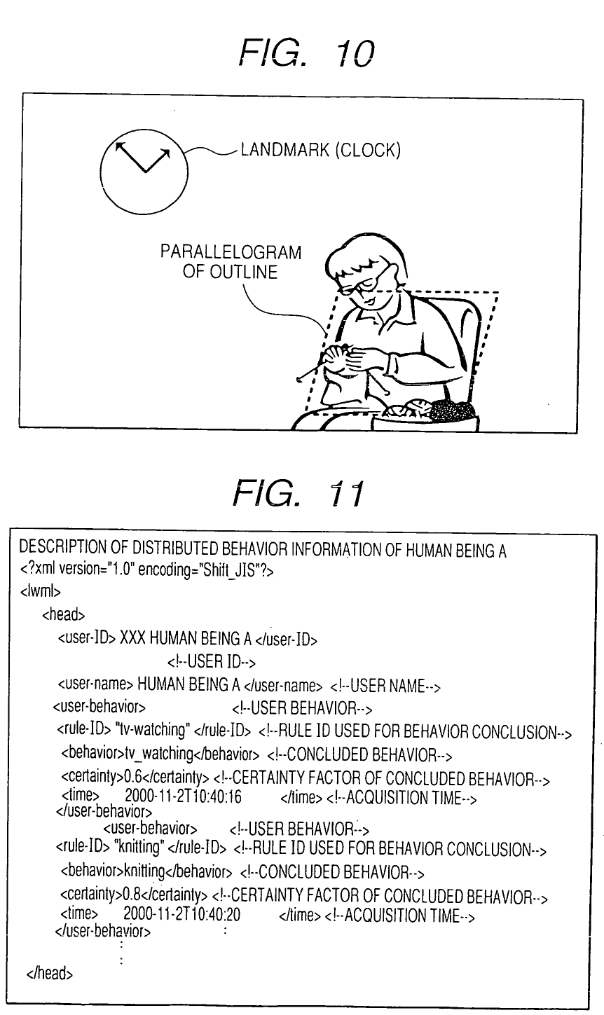

When the normalized pattern as shown in FIG. 8D is cut out, authentication is performed as to whether the cut-out face image corresponds to one of the family members or not. The authentication is performed as follows. In the normalized pattern in FIG. 8D, shading values are arranged in m rows by n columns as shown in FIG. 9A. This can be converted into a vector expression as shown in FIG. 9B. A feature vector Nₖ (k designates how many normalized patterns have been obtained for the same person till then) is used for subsequent calculation.

A feature quantity to be used for recognition is a subspace having a reduced number of data dimensions of orthogonal vectors obtained by obtaining a correlation matrix of the feature vectors and calculating a KL expansion thereof. The correlation matrix C is expressed by the following expression.

$$C = \frac{1}{r} {\sum }_{k = 1}^{r} {N}_{k} {N}_{k}^{T} \qquad [ Expression 2 ]$$

Incidentally, r designates the number of normalized patterns acquired for the same person. When the correlation matrix C is diagonalized, main components (eigenvectors) are obtained. Of the eigenvectors, M eigenvectors having the large eigen values are used as a subspace, which corresponds to a dictionary for personal authentication.

For the personal authentication, a feature quantity extracted in advance has to be registered beforehand in this dictionary together with index information of the person in question, such as an ID number and a subspace (eigen values, eigenvectors, the number of dimensions, the number of sample data). The personal authentication portion 1021 compares and checks the feature quantity extracted from a photographed face image with the feature quantity registered in the dictionary (for example, see Kazuhiro Fukui and Osamu Yamaguchi, id.).

When the human being A is authenticated as a result of the checking, information about the position of the human being A indicating that the human being A is in the living room is described together with the sensor IDs acquired by the cameras 1013-B and 2022 as shown in FIG. 7.

Due to a long distance between the camera 1013-B and the human being A, the face image photographed by the camera 1013-B is so small in size as to have an area 0.7 times as large as an area that can secure the certainty factor of 1. Further, the similarity is 0.9 in face recognition. The original accuracy of the camera 1013-B is 1.0. Therefore, the certainty factor grant portion 103 grants a certainty factor of 0.63 by the calculation 1.0×0.7×0.9=0.63. If there is a change in the installation environment of the camera 1013-B, the accuracy will be out of 1.0, and the certainty factor will be lowered correspondingly. The same thing is applied to the other members such as microphones.

Likewise, due to a short distance from the camera 2022 of the robot B (202), the face image acquired can have an area of 0.89 times. The original accuracy of the camera 2022 is 1.0. Further, the similarity is 0.9 in face recognition. Therefore, the certainty factor grant portion 103 grants a certainty factor of 0.8 by the calculation 1.0×0.89×0.9=0.8.

In the same manner, the action recognition portion 1024 recognizes the body direction and the face direction of the human being A by the image recognition portion 1022 based on the image of the camera 2022, and describes them together with their certainty factors as shown in FIG. 7. In the case of the camera 1013-B fixed to the wall, the coordinate position of the camera 1013-B and the normal direction thereto are known as shown in FIG. 3 even when the camera is panned. Therefore, the direction of the taken body or face can be calculated from the coordinate position and the normal direction.

On the other hand, the camera 2022 attached to the robot is movable. Therefore, the position or direction of the camera 2022 is not known as in the camera 1013-B. In such a case, for example, a clock or a picture decorated on the wall of the room, or a TV set, a refrigerator, a microwave oven, or the like, placed at the wall is used as a landmark.

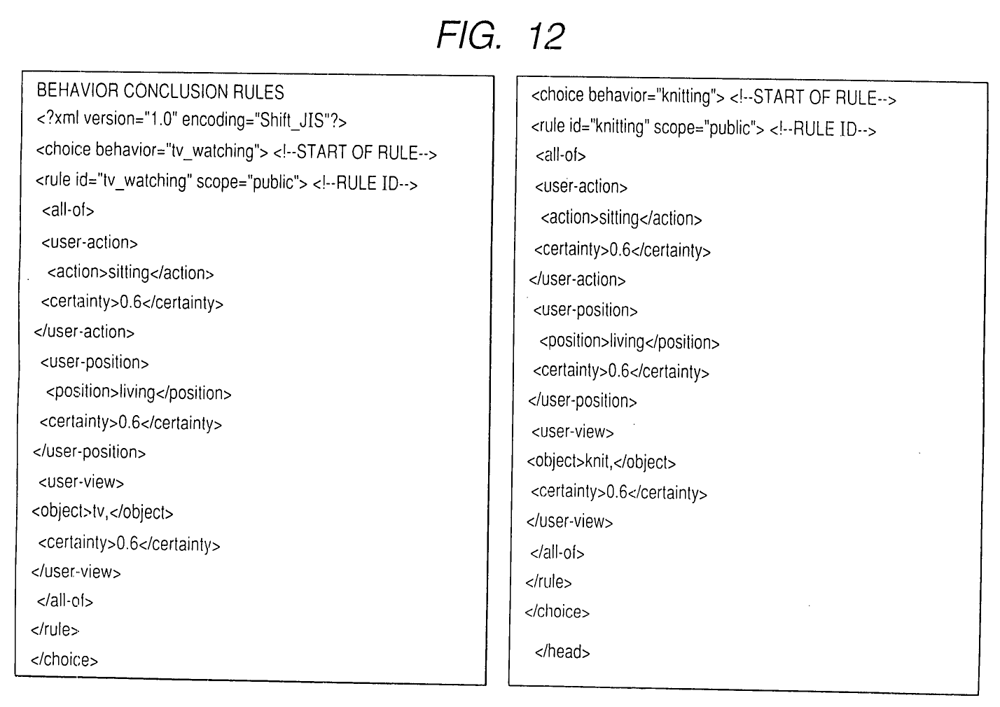

For example, as shown in FIG. 10, the camera 2022 is panned or tilted to be right opposed to the clock as a landmark (in this case the camera is panned or tilted so that the clock looks round because the clock is circular). In this state, the outline of the human body is extracted by thinning or the like, and a parallelogram covering the outline is found out. The direction of the human body can be found by obtaining a normal to the parallelogram. In the same manner, the direction of the face is found from a quadrilateral formed out of lines obtained by connecting both eyes and both nostrils as shown in FIGS. 8A to 8D.

Further, based on the image of the camera 2022, it is known that the human being A is sitting. That is, as shown in FIG. 10, it is known from the positions and the dimensions of the clock as a landmark and the human face that the face of the human being is lower in position than his/her height.

In the aforementioned example, while an image is picked up by a camera, personal recognition/authentication is carried out concurrently. The invention is not always limited to this manner. For example, from the position sensor 1013-A, the distributed ambient behavior processing portion 102 can know that the human being A is in the living room. Upon knowing of the existence of the human being A, the distributed ambient behavior processing portion 102 may retrieve all the sensor information of the sensors located in the living room, as to whether there is any other information about the human being A at the same time (with the same time stamp or including the same time stamp) or not, and perform personal recognition/authentication. Here, description has been made on personal authentication based on image recognition. A certainty factor can be calculated likewise about voice recognition. As described above, a certain factor with a time stamp is calculated at any time based on information collected by sensors such as cameras, microphones and position sensors.

FIG. 11 shows behaviors of the human being A recognized by the behavior recognition portion 1025 based on sensor information and action information and in accordance with behavior rule knowledge. The recognized behaviors are additionally written in the distributed behavior information DB 114 through the distributed ambient behavior edition portion 104.

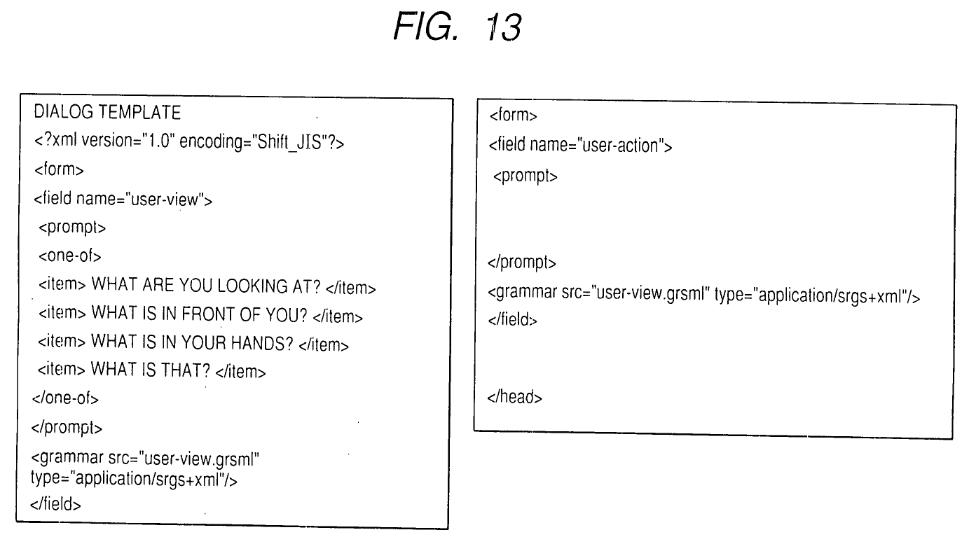

FIG. 12 shows an example of the behavior rule knowledge used by the behavior recognition portion 1025. For example, a behavior “tv_watching” (watching TV) is judged as “tv_watching” (watching TV) when satisfying the conditions:
the certainty factor about the fact that the user is in “living” (living room) is not lower than 0.6;
the certainty factor about the fact that the user is “sitting” is not lower than 0.6; and
the certainty factor about the fact that “tv” (TV set) is in the field of view of the user is not lower than 0.6.

Likewise, a behavior is judged as “knitting” when satisfying the conditions:
the certainty factor about the fact that the user is in “living” (living room) is not lower than 0.6;
the certainty factor about the fact that the user is “sitting” is not lower than 0.6; and
the certainty factor about the fact that “knit” is in the field of view of the user is not lower than 0.6.

As shown in FIG. 7, at the time of 2000-11-2T10:40:15, the position of the human being A acquired by the position sensor 1013-A is “living”. However, the certainty factor of that fact is 0.48, which does not satisfy the condition of the certainty factor's being not lower than 0.6.

On the other hand, at the time of 2000-11-2T10:40:16, the position of the human being A acquired by the camera 1013-B is “living”. In addition, the certainty factor of that fact is 0.63, which satisfies the condition of the certainty factor's being not lower than 0.6.

Further, the action of the human being A acquired by the camera 1013-B is “sitting”. In addition, the certainty factor of that fact is 0.6, which satisfies the condition of the certainty factor's being not lower than 0.6. At the time of 2000-11-2T10:40:16, the face direction acquired by the camera 2022 is (px31, py31, pz31), and its certainty factor is 0.6. For example, when the camera 2022 looks in the face direction, it can be confirmed that the TV set as a landmark of the living room is in the field of view. That is, the certainty factor about that the TV set is in the field of view of the user is not lower than 0.6.

As described above, all the conditions of “tv_watching” (watching TV) are satisfied. By the behavior recognition portion, it is therefore determined that the behavior at the time of 2000-11-2T10:40:16 is “tv_watching” (watching TV) as shown in FIG. 11. The certainty factor of the behavior is 0.6 which is the minimum of the certainty factors (0.63, 0.6, 0.6) of the three conditions.

Likewise, at the time of 2000-11-2T10:40:20, the position of the human being A acquired by the camera 2022 is “living”. In addition, the certainty factor of that fact is 0.8, which satisfies the condition of the certainty factor's being not lower than 0.6. Further, the action of the human being A acquired by the camera 2022 is “sitting”. In addition, the certainty factor of that fact is 0.8, which satisfies the condition of the certainty factor's being not lower than 0.6. At the time of 2000-11-2T10:40:20, the face direction acquired by the camera 2022 is (px32, py32, pz32), and its certainty factor is 0.8. In fact the user is looking at a knit in hand in this face direction. However, the fact that the TV set as a landmark of the living room is absent in the field of view in the face direction, and any other landmark is not present can be confirmed, for example, when the camera 2022 looks in the face direction.

Here, the behavior recognition portion 1025 sends a dialog request to the communication control portion 105 in order to confirm what is in the view field of the user as a behavior determination condition. The communication control portion 105 generates a dialog based on a dialog template in the communication generating portion 106. For example, the dialog template has a configuration as shown in FIG. 13.

In FIG. 13, for example, a dialog template is described for each field name corresponding to a not-filled condition. Here, “user-view” is not filled. Therefore, “user-view” is sent to the communication generating portion 106, and a dialog template for filling the field “user-view” is applied. As a dialog to be produced, <one-of > (one of) “what are you looking at?”, “what is in front of you?”, “what is in your hands?” and “what is that?” is applied and produced. The selected prompt is sent to the media conversion portion 107, which performs speech synthesis. The result of the speech synthesis is presented from a speaker 2021 of the robot B (202) serving as the communication representation portion 108.

An answer of the human being A to the speech is voice-recognized by user-view.grsml. The accuracy of the voice recognition corresponds to the certainty factor of “user-view”. In this case, for example, it is 0.85. As a result of the recognition, for example, the field “user-view” is filled with “knit”. Thus, all the conditions of “knitting” are satisfied. The certainty factor of the behavior is 0.8 which is the minimum of the certainty factors (0.8, 0.8, 0.85) of the three conditions.

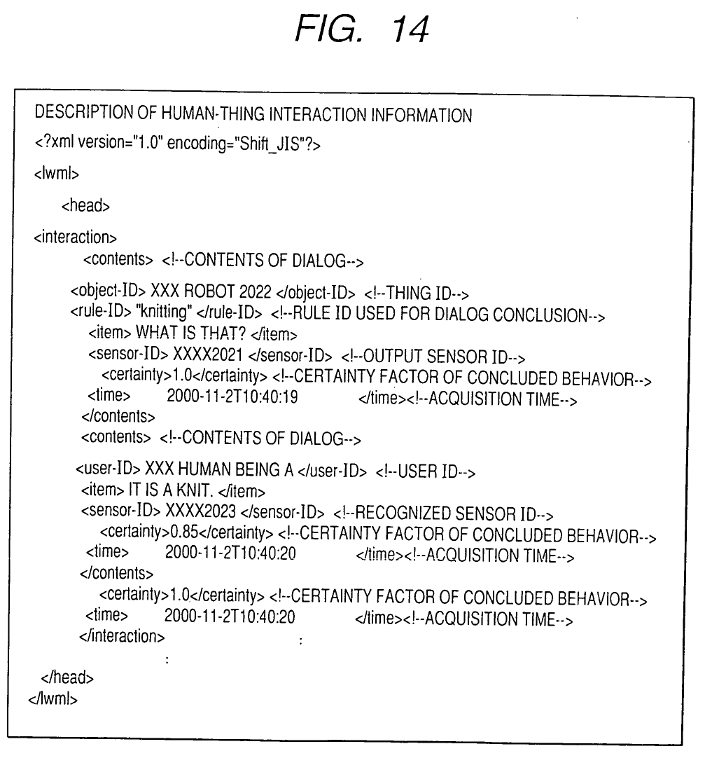

In addition, an interaction occurs due to this dialog between the robot B (202) and the human being A. As a result, for example, the interaction is described in the human beings-things interaction DB 116 as shown in FIG. 14.

The dialog produced by the robot B (202) conforms to a rule. The ID of the robot where the rule emerged, the device which outputs the dialog, and the actual contents of the dialog are described. On the other hand, there is no special rule on the human being A side. The result of the recognition is described together with the sensor ID of the microphone used for the recognition.

In this embodiment, the certainty factor calculated by the certainty factor grant portion 103 is the minimum value of products of sensor accuracy values for three conditions by way of example. The invention is not always limited to this manner.

For example, the accuracy of personal recognition/authentication based on images can be increased by learning acquired images. In the same manner, the settings of certainty factor conditions for rules can be varied by learning the rules or the like. Assume that the human being D is placing dishes on a table as shown in FIG. 2. When the face of the human being D is looking toward the dishes, the human being D is concerned with the positions of the dishes, and the certainty factor is high. On the other hand, when the face is not looking toward the dishes, the human being D is not so concerned with the positions of the dishes. Thus, the certainty factor is low. In such a manner, the certainty factor may be varied in accordance with the face direction recognized by image recognition.

Here, description has been made on the human beings-things interaction DB 116. The human-service interaction DB 115 and the human beings-human beings interaction DB 117 can be described in the same manner.

As described above, according to the configuration of this embodiment, a certainty factor can be varied at any time based on accuracy information of sensor detection, and dialog information with a human being. With this certainty factor, a robot can have a dialog and acquire necessary information. Thus, a non-weighted natural dialog can be achieved, and continuous dialog control can be performed.

1. A communication apparatus comprising:
a sensor input portion;
a distributed sensor storage portion which stores sensor information from the sensor input portion in association with sensor type information or an attribute;
a distributed ambient behavior processing portion which performs processing of recognition based on the sensor information stored in the distributed sensor storage portion;
a certainty factor grant portion which grants a certainty factor in accordance with a result of recognition of the distributed ambient behavior processing portion; and
a distributed ambient behavior storage portion which stores the result of recognition of the distributed ambient behavior processing portion as recognition information and the certainty factor granted by the certainty factor grant portion in association with the sensor information of the distributed sensor storage portion.

2. The communication apparatus according to claim 1, further comprising:
a distributed ambient behavior edition portion which reads the sensor information stored in the distributed sensor storage portion, and corrects the recognition information and the certainty factor based on the sensor information,
wherein the recognition information and the certainty factor are stored in the distributed ambient behavior storage portion.

3. The communication apparatus according to claim 1, further comprising:
a communication control portion which performs communication control based on the recognition information and the certainty factor stored in the distributed ambient behavior storage portion;
a communication generating portion which generates a communication under control of the communication control portion; and
a communication presentation portion which presents a result generated by the communication generating portion.

4. The communication apparatus according to claim 2, further comprising:
a communication control portion which performs communication control based on the recognition information and the certainty factor stored in the distributed ambient behavior storage portion;
a communication generating portion which generates a communication under control of the communication control portion; and
a communication presentation portion which presents a result generated by the communication generating portion.

5. The communication apparatus according to claim 1,
wherein the distributed ambient behavior processing portion includes a personal authentication portion which authenticates a person to be authenticated, and
the certainty factor grant portion grants a certainty factor in accordance with a result of authentication of the personal authentication portion.

6. The communication apparatus according to claim 1,
wherein the certainty factor grant portion grants a certainty factor in accordance with accuracy information of the sensor input portion as a result of recognition based on the sensor information.

7. A communication method comprising:
storing sensor information from a sensor input portion in association with sensor type information or an attribute by means of a distributed sensor storage portion;
performing processing of recognition based on the sensor information by means of a distributed ambient behavior processing portion;
granting a certainty factor in accordance with a result of recognition of the distributed ambient behavior processing portion by means of a certainty factor grant portion; and
storing the result of recognition and the certainty factor in association with the sensor information of the distributed sensor storage portion by means of a distributed ambient behavior storage portion.
